(19) United States
(12) Patent Application Publication
(10) Pub. No.: US 2026/0190796 A1
(43) Pub. Date: Jul. 2, 2026

(54) DISPLAY APPARATUS

(71) Applicant: LG Display Co., Ltd., Seoul (KR)

(72) Inventor: Tae-Hyun MIN, Paju-si (KR)

(73) Assignee: LG Display Co., Ltd., Seoul (KR)

(21) Appl. No.: 19/391,315

(22) Filed: Nov. 17, 2025

(30) Foreign Application Priority Data
Dec. 30, 2024 (KR) 10-2024-0200600

(51) Int. Cl. H10K 59/80; H10K 59/121; H10K 59/131; H10K 102/00

(52) U.S. Cl. CPC H10K 59/874; H10K 59/1213; H10K 59/131; H10K 59/873; H10K 2102/311

(57) ABSTRACT

A display apparatus according to one or more examples includes a substrate, a display area having a plurality of sub-pixels, a non-display area outside the display area, a transistor and a light emitting device disposed in each of the plurality of sub-pixels, a voltage line disposed in the non-display area to supply a voltage from outside to the display area, and a moisture blocking pattern disposed at at least one side of the voltage line. The moisture blocking pattern includes the first moisture blocking pattern layer, the second moisture blocking pattern layer, the third moisture blocking pattern layer having a smaller width than the first moisture blocking pattern layer and the second moisture blocking pattern layer, and the fourth moisture blocking pattern layer surrounding the first to third moisture blocking pattern layers.

### CROSS-REFERENCE TO RELATED APPLICATIONS

This application claims the benefit of and priority to Korean Patent Application No. 10-2024-0200600, filed in the Republic of Korea on Dec. 30, 2024, the entire contents of which are incorporated herein by reference for all purposes.

### BACKGROUND

### 1. Technical Field

The present disclosure relates to a display apparatus, and particularly to, for example, without limitation, a display apparatus capable of cracks.

### 2. Description of Related Art

In recent years, as multimedia is developed, the importance of display apparatus is increasing. In response to this, display apparatus such as liquid crystal display, plasma display, and organic light emitting display are being commercialized. Among these display apparatuses, the organic light emitting display having a high response speed, a high luminance, and a wide view angel is currently widely used.

The organic light emitting device of the organic light emitting display apparatus is highly susceptible to foreign substances such as moisture and oxygen. When the organic light emitting device is exposed to foreign substances such as moisture or oxygen, there are problems such as pixel shrinkage, which reduces the light-emitting area, and dark spot defects.

The description of related art should not be considered prior art merely because it is mentioned in or associated with this section. The description of related art includes information that describes one or more aspects of the subject technology, and the description in this section does not limit the scope of the present disclosure.

### SUMMARY

An aspect of the present disclosure is to provide a display apparatus capable of preventing moisture penetration due to cracks by alleviating a step difference of a moisture blocking pattern formed in a voltage line.

Another aspect of the present disclosure is to provide a more robust display apparatus by providing a new structure of a moisture blocking pattern capable of dispersing an external force.

In order to achieve the aspect, a display apparatus according to one or more examples of the present disclosure comprises a substrate, a display area having a plurality of sub-pixels, a non-display area outside the display area, a transistor and a light emitting device disposed in each of the plurality of sub-pixels, a voltage line disposed in the non-display area to supply a voltage from outside to the display area, and a moisture blocking pattern disposed at at least one side of the voltage line, wherein the moisture blocking pattern includes the first moisture blocking pattern layer, the second moisture blocking pattern layer, the third moisture blocking pattern layer having a smaller width than the first moisture blocking pattern layer and the second moisture blocking pattern layer, and the fourth moisture blocking pattern layer surrounding the first, second, and third moisture blocking pattern layers.

The light emitting device may include a first electrode, a light emitting layer on the first electrode, and a second electrode on the light emitting layer, and the fourth moisture blocking pattern layer may be made of the same material as the first electrode of the light emitting device.

The moisture blocking pattern further may include a fifth moisture blocking pattern layer surrounding the fourth moisture blocking pattern layer, and the fifth moisture blocking pattern layer may be made of the same material as the second electrode of the light emitting device.

The non-display area may include a bending area, and the moisture blocking pattern may be disposed between the bending area and the display area.

The voltage line may include a low potential voltage line and the moisture blocking pattern may be integrally formed with the low potential voltage line.

The moisture blocking pattern may include a plurality of hammer shaped patterns.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further features, advantages, and aspects are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a schematic block diagram of an organic light emitting display apparatus according to one or more examples of the present disclosure.

FIG. 2 is the schematic block diagram of a sub-pixel of the organic light emitting display apparatus according to one or more examples of the present disclosure.

FIG. 3 is a circuit diagram conceptually showing the sub-pixel of the organic light emitting display apparatus according to one or more examples of the present disclosure.

FIG. 4 is a perspective view illustrating a structure of the display apparatus according to one or more examples of the present disclosure.

FIG. 5 is a plan view of the display apparatus according to one or more examples of the present disclosure.

FIGS. 6A and 6B are enlarged plan views of areas A and B of FIG. 5, respectively.

FIGS. 7A and 7B are cross-sectional views illustrating the display apparatus in accordance with a first embodiment of the present disclosure, respectively, and are cross-sectional views taken along a line I-I′ and a line II-II′ of FIG. 5.

FIGS. 8A and 8B are enlarged cross-sectional views of a connection pattern and a moisture blocking pattern of the display apparatus according to the first embodiment of the present disclosure, respectively.

FIG. 9 is the view showing a structure in which a fourth moisture blocking pattern layer surrounding the first to third moisture blocking pattern layers is not disposed.

FIG. 10 is the enlarged cross-sectional view of the blocking pattern of the display apparatus according to a second embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, electrodes, structures, transistors, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. Any references to singular may include plural, and vice versa, unless expressly stated otherwise. In one or more examples, unless expressly stated otherwise, an element may be one or more elements; and an element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, electrodes, structures, transistors, sections, members, parts, regions, areas, portions, and/or the like) are described using any of the terms such as “on,” “on a top of,” “upon,” “on top of,” “over,” “under,” “above,” “upper,” “at an upper portion,” “at a upper side,” “below,” “lower,” “at a lower portion,” “at a lower side,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” “A,” “B,” “(a),” “(b),” and the like may be used herein to describe various elements (e.g., layers, films, components, electrodes, structures, transistors, sections, members, parts, regions, areas, portions, steps, operations, and/or the like), these elements should not be limited by these terms, for example, to any particular order, precedence, or number of elements. Further, these are not used to define the essence or basis of the elements. These terms are merely used to refer to one element separately from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

The expression that an element (e.g., layer, film, component, electrode, structure, transistor, section, member, part, region, area, portion, or the like) “is engaged” with another element may be understood, for example, as that the element may be either directly or indirectly engaged with the another element. The term “is engaged” or similar expressions may refer to a term such as “covers,” “surrounds,” “is in contact,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between the element and the another element, unless otherwise specified. Further, the element may be engaged at least partially or entirely (or completely) with the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally. For example, the terms “first direction,” “second direction,” “side direction,” “rear direction,” and the like should not be interpreted only based on a geometrical relationship in which the respective directions are parallel, perpendicular, diagonal, or slanted with respect to each other, and may be meant as directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “some,” “at least some portions,” “at least some parts,” “at least a portion,” “at least one or more portions,” “at least a part,” “at least one or more parts,” “at least some elements,” “one or more,” or the like of a plurality of elements can represent (i) one element of the plurality of elements, (ii) a portion (or a part) of the plurality of elements, (iii) one or more portions (or parts) of the plurality of elements, (iv) one or more elements of the plurality of elements, (v) multiple elements of the plurality of elements, or (vi) all of the plurality of elements. Moreover, “at least some,” “some,” “at least some portions,” “at least some parts,” “at least a portion,” “at least one or more portions,” “at least a part,” “at least one or more parts,” or the like of an element can represent (i) a portion (or a part) of the element, (ii) one or more portions (or parts) of the element, (iii) the element, or (iv) all portions of the element.

The expression of a first element, a second elements “and/or” a third element should be understood as any one of the first, second and third elements or as any or all combinations of the first, second and third elements. Similar interpretations apply to the use of “and/or” with two elements or with more than three elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

A phrase “substantially the same” or “nearly the same” may indicate a degree of being considered as being equivalent to each other taking into account minute differences due to errors in the manufacturing process.

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same or similar elements may be illustrated in other drawings, and like reference numerals may refer to like or similar elements unless stated otherwise. The same or similar elements may be denoted by the same reference numerals even if they are depicted in different drawings. Repetitive descriptions of the same or similar elements may be omitted for brevity, and the descriptions provided for elements in one or more figures may also apply to elements in other figures that use the same or similar reference numerals unless stated otherwise. In addition, for the convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

In one or more aspects, the term “apparatus” may include a display apparatus such as a liquid crystal module (LCM) including a display panel and a driving unit for driving the display panel, and an organic light emitting display module (OLED module). Further, the term “apparatus” may further include a notebook computer, a television, a computer monitor, a vehicle electric apparatus including an apparatus for a vehicle or other type of vehicle, and a set electronic apparatus or a set apparatus such as a mobile electronic apparatus of a smart phone or an electronic pad, etc., which are a finished product (complete product or final product) including an LCM and an OLED module.

Accordingly, in one or more aspects, an apparatus of the present disclosure may include the display apparatus itself such as an LCM, an OLED module, etc., and the application product including an LCM, an OLED module, or the like, or the set apparatus, which is the apparatus for end users.

Hereinafter, one or more aspects of the present disclosure will be described in detail with reference to the accompanying drawings.

The display apparatus of the present disclosure may be applied to various display apparatuses such as an organic light emitting display apparatus, a liquid crystal display apparatus, an electrophoretic display apparatus, a quantum dot display apparatus, a light emitting apparatus, micro LED display apparatus, and a mini LED display apparatus. However, in the following description, the organic light emitting display apparatus is described for convenience of explanation as an example.

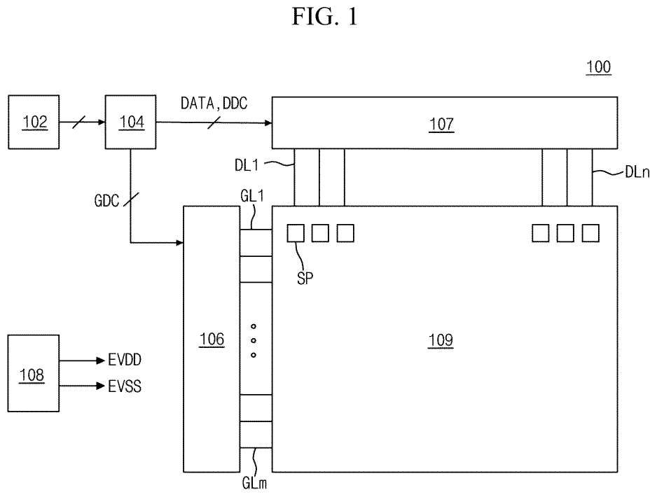

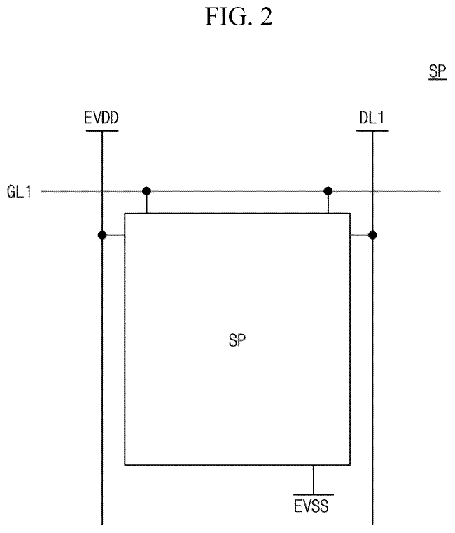

FIG. 1 is the schematic block diagram and FIG. 2 is the schematic block diagram of the sub-pixel of the organic light emitting display apparatus according to one or more examples of the present disclosure.

As shown in FIG. 1, the organic light emitting display apparatus 100 includes an image processing unit 102, a timing controlling unit 104, a gate driving unit 106, a data driving unit 107, a power supplying unit 108, and a display panel 109.

The image processing unit 102 outputs an image data supplied from outside and a driving signal for driving various devices. For example, the driving signal from the image processing unit 102 can include a data enable signal, a vertical synchronizing signal, a horizontal synchronizing signal, and a clock signal.

The image data and the driving signal are supplied to the timing controlling unit 104 from the image processing unit 102. The timing controlling unit 104 writes and outputs gate timing controlling signal GDC for controlling the driving timing of the gate driving unit 106 and data timing controlling signal DDC for controlling the driving timing of the data driving unit 107 based on the driving signal from the image processing unit 102.

The gate driving unit 106 outputs the scan signal to the display panel 109 in response to the gate timing control signal GDC supplied from the timing controlling unit 104. The gate driving unit 106 outputs the scan signal through a plurality of gate lines GL1 to GLm. In this case, the gate driving unit 106 may be formed in the form of an integrated circuit (IC), but is not limited thereto.

The data driving unit 107 outputs the data voltage to the display panel 109 in response to the data timing control signal DDC input from the timing controlling unit 104. The data driving unit 107 samples and latches the digital data signal DATA supplied from the timing controlling unit 104 to convert it into the analog data voltage based on the gamma voltage. The data driving unit 107 outputs the data voltage through the plurality of data lines DL1 to DLn. In this case, the data driving unit 107 may be mounted on the upper surface of the display panel 109 in the form of an integrated circuit (IC), but is limited thereto.

The power supplying unit 108 outputs a high potential voltage VDD and a low potential voltage VSS etc. to supply these to the display panel 109. The high potential voltage VDD is supplied to the display panel 109 through the first power line EVDD and the low potential voltage VSS is supplied to the display panel 109 through the second power line EVSS. In this time, the voltage from the power supplying unit 108 are applied to the data driving unit 107 or the gate driving unit 106 to drive thereto.

The display panel 109 displays the image based on the data voltage from the data driving unit 108, the scan signal from the gage driving unit 106, and the power from the power supplying unit 108.

The display panel 109 includes a plurality of sub-pixels SP to display the image. The sub-pixel SP can include Red sub-pixel, Green sub-pixel, and Blue sub-pixel. Further, the sub-pixel SP can include White sub-pixel, the Red sub-pixel, the Green sub-pixel, and the Blue sub-pixel. The White sub-pixel, the Red sub-pixel, the Green sub-pixel, and the Blue sub-pixel may be formed in the same area or may be formed in different areas.

As shown in FIG. 2, one sub-pixel SP may be connected to the gate line GL1, the data line DL1, the first power line EVDD, and the second power line EVSS. The number of transistors and capacitors and a driving method of the sub-pixel SP are determined according to the configuration of the pixel circuit.

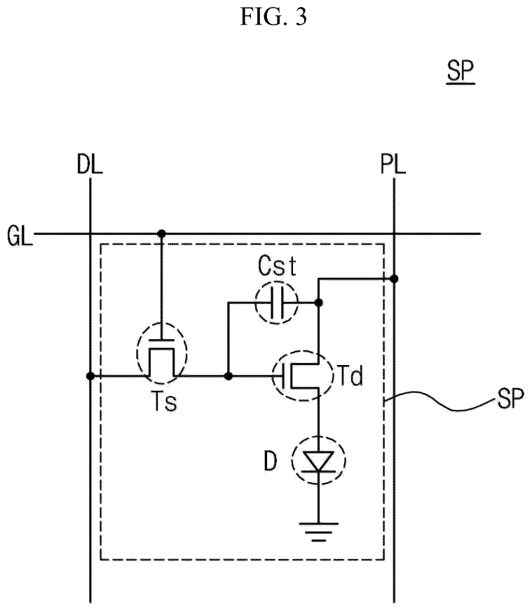

FIG. 3 is the circuit diagram illustrating the sub-pixel SP of the organic light emitting display apparatus 100 according to one or more examples of the present disclosure.

As shown in FIG. 3, the organic light emitting display apparatus 100 according to one or more examples of the present disclosure includes the gate line GL, the data line DL, and the power line PL crossing each other for defining the sub-pixel SP. A switching thin film transistor Ts, a driving thin film transistor DT, a storage capacitor Cst, and an organic light emitting device D are disposed in the sub-pixel SP.

The switching thin film transistor Ts is connected to the gate line GL and the data line DL, and the driving thin film transistor Td and the storage capacitor Cst are connected between the switching thin film transistor Ts and the power line PL. The organic light emitting device D is connected to the driving thin film transistor Td.

In the organic light emitting display apparatus having this structure, when the switching thin film transistor Ts is turned on according to the gate signal applied to the gate line GL, the data signal applied to the data line DL is applied to the gate electrode of the driving thin film transistor Td and one electrode of the storage capacitor Cst through the switching thin film transistor Ts.

The driving thin film transistor Td is turned on according to the data signal applied to the gate electrode. As a result, the current proportional to the data signal is supplied to the organic light emitting device D from the power line PL through the driving thin film transistor Td and then the organic light emitting device D emits light with a luminance proportional to the current flowing through the driving thin film transistor Td.

At this time, the storage capacitor Cst is charged with the voltage proportional to the data signal to keep the voltage of the gate electrode of the driving thin film transistor Td constant for one frame.

In the figure, only two thin film transistors Td and Ts and one capacitor Cst are provided, but the present disclosure is not limited thereto. Three or more thin film transistors and two or more capacitors may be provided in the present disclosure.

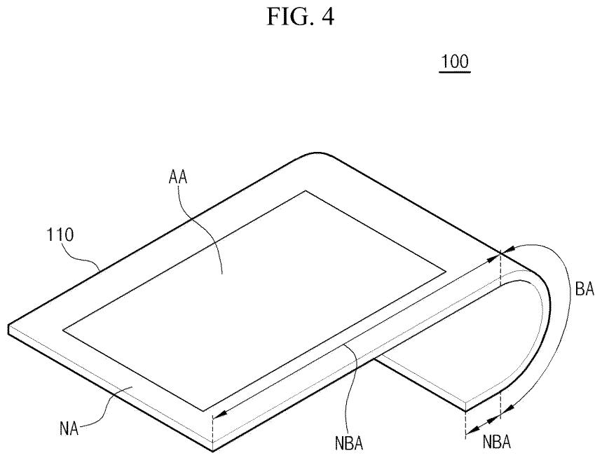

FIG. 4 is a perspective view illustrating the structure of the display apparatus 100 according to one or more examples of the present disclosure.

As shown in FIG. 4, the display apparatus 100 according to one or more examples of the present disclosure includes a bending area BA and a non-bending area NBA. The non-bending area NBA may include two or more areas. For example, in the display apparatus 100 according to one or more examples of the present disclosure, the bending area BA may be disposed between two non-bending areas NBAs. The bending area BA is the area in which a portion of the substrate 110 is bent. For example, the bending area BA is the area in which a portion of the substrate 110 is bent in order to arrange the pad unit and the external module bonded to the pad portion on the rear surface side of the substrate 110.

As the bending area BA is bent in the rear direction of the substrate 110, the external module bonded to the pad unit of the substrate 110 moves toward the rear surface of the substrate 110. Therefore, since the external module may not be visible when viewed from the front of the substrate 110, the size of the non-display area NA visible from the front may be reduced, thereby implementing a narrow bezel.

The non-bending area NBA is the area in which the display apparatus 100 is not bent. The two areas of the non-bending area NBA may face each other.

A plurality of pixels may be disposed in a partial area of the non-bending area NBA. For example, the plurality of pixels may be formed in the display area AA disposed in the non-bending area NBA.

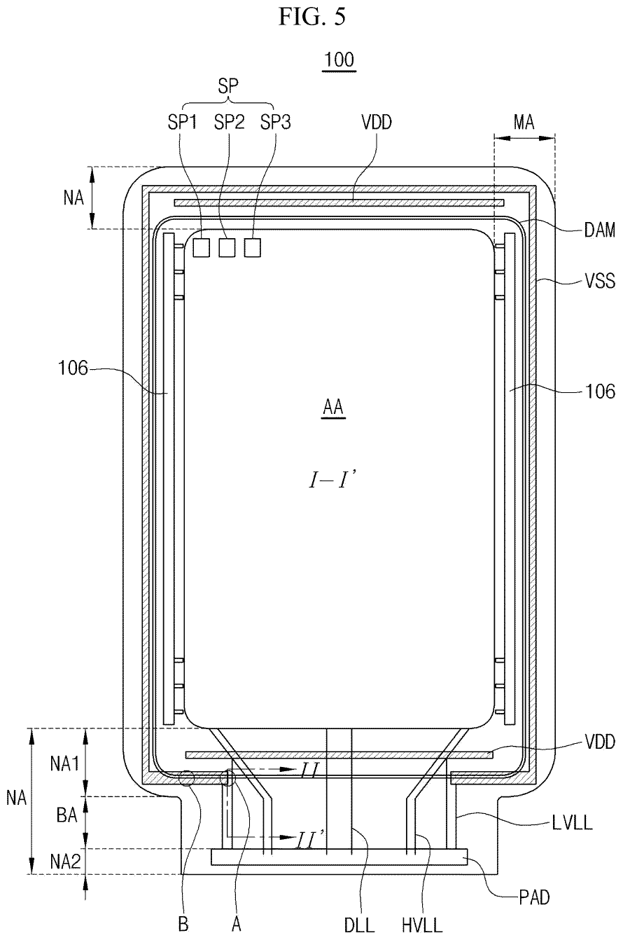

FIG. 5 is a plan view of a display apparatus 100 according to one or more examples of the present disclosure. As shown in FIG. 5, the display apparatus 100 includes an active area AA in which an image is displayed and a non-active area NA surrounding the display area AA.

The pixel P including a plurality of sub-pixels SP1, SP2, and SP3 is disposed in the display area AA. Each of the plurality of sub-pixels SP is an individual unit that emits light. The sub-pixel SP may include a red sub-pixel that emits red, a blue sub-pixel that emits blue, and a green sub-pixel that emits green. Further, a white sub-pixel that emits white may be included. A light emitting device and a thin film transistor are disposed in each of the sub-pixel SP1, SP2, and SP3 of the display area AA.

In the non-display area NA in which the image is not displayed, various signal lines and driving circuits for driving the plurality of sub-pixels SP1, SP2, and SP3 in the display area AA are disposed.

The non-display area NA may be formed outside the display area AA so as to surround the display area AA. In this case, the non-display area NA in the lower end portion of the display area AA may include first and second non-display areas NA1 and NA2 and a bending area BA. As the bending area BA is bent, the first non-display area NA1 is disposed in the front surface of the display apparatus 100, and the second non-display area NA2 is disposed in the rear surface of the display apparatus 100.

The first non-display area NA1 may be the area in which various signal lines are disposed. For example, a part of the low potential voltage line VSS and a part of the high potential voltage line VDD may be disposed in the first non-display area NA1. In this case, the low potential voltage line VSS may be integrally formed to extend to the left and right sides and upper side of the display area AA. The low potential voltage line VSS is connected to the pad PAD through the low potential voltage link line LVLL to supply a low potential voltage from the outside, and applies the supplied low potential voltage to the sub-pixels SP1, SP2, and SP3.

The high potential line VDD may be disposed in the first non-display area NA1 in the lower portion of the display area AA and the non-display area NA in the upper portion of the display area AA. The high potential voltage line VDD is connected to the pad PAD through the high potential voltage link line HVLL to supply a high potential voltage from the outside, and applies the supplied high potential voltage to the sub-pixels SP1, SP2, and SP3.

The second non-display area NA2 may be a pad area. The pad PAD is disposed in the second non-display area NA2. Although not shown in the drawing, a flexible circuit board such as a flexible printed circuit board (FPC), a chip on film (COF), etc. may be attached to the pad PAD so that an external signal may be supplied to the inside of the display apparatus 100.

A dam DAM may be formed in the non-display area NA. The dam DAM is formed in the non-display area NA in a closed curve shape surrounding the display area AA. When an encapsulation layer (not shown) is formed by coating an organic material, the dam DAM may limit the end of the organic encapsulation layer to prevent the organic encapsulation layer from flowing down or collapsing.

Although only one dam DAM is disposed in the drawing, a plurality of dams DAM may be disposed at preset intervals. Further, in the drawing, the dam DAM is disposed inside the low potential voltage line VSS, but may also be disposed outside the low potential voltage line VSS.

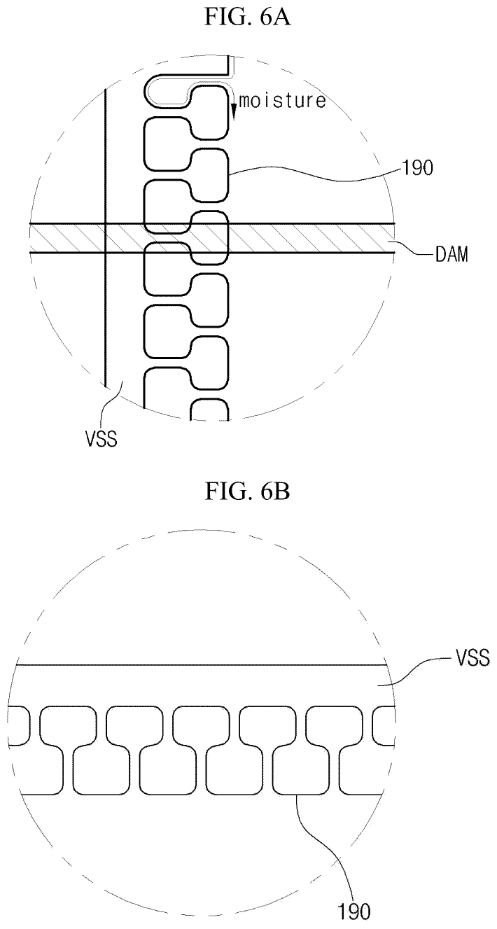

FIGS. 6A and 6B are enlarged plan views of areas A and B of FIG. 5, respectively, and showing low potential voltage line VSS.

As shown in FIGS. 6A and 6B, a plurality of moisture blocking patterns 190 are formed at an outer edge of the low potential voltage wiring VSS. The moisture blocking pattern 190 extends the penetration distance of the moisture penetrating through the low potential voltage line VSS from the outside to block moisture penetrating into the display apparatus 100. In particular, since the edge of the low potential voltage line VSS shown in FIG. 6A is the area which is extended from the outside to the inside of the display apparatus 100, the moisture penetrating through this area may directly reach the inside of the display apparatus 100, but by forming the moisture blocking pattern 190, the moisture penetration through this area may be prevented.

As shown in the drawings, each of the plurality of moisture blocking patterns 190 may be formed in a hammer shape, but is not limited thereto. The moisture blocking pattern 190 may have any shape as long as the distance by which the moisture moves may be extended.

The moisture blocking pattern 190 may be formed at various positions of the display apparatus 100. The moisture blocking pattern 190 may be formed along the entire outer edge of the low potential voltage line VSS or may be formed only in the area where the moisture penetration is well generated. Further, the moisture blocking pattern 190 may be formed only near the bending area BA in which stress increases due to bending. For example, as illustrated in FIG. 6A, the moisture blocking pattern 190 may be formed near the bending area BA, particularly at the end of the low potential voltage line VSS disposed near the bending area BA. That is, the moisture blocking pattern 190 may be formed in area A of the low potential voltage line VSS extending from the display area AA to the bending area BA. Further, the moisture blocking pattern 190 may be formed only in area B of the low potential voltage line VSS in the corner area B of the rounded display apparatus 100. However, the present disclosure is not limited to such a configuration, and the moisture blocking pattern 190 may be disposed in various areas of the display apparatus 100.

Referring to FIGS. 6A and 6B, the moisture blocking pattern 190 may include a plurality of structures arranged in a row or a column in a plan view (e.g., side by side, or in a linear array, either horizontally or vertically), along the low potential voltage line VSS. Each of the plurality of structures may include an elongated member and a polygonal member. The elongated member may have a central region of uniform width and oppositely disposed end regions of increased width. One end of the elongated member may be integrally merged with the polygonal member. The other end of the elongated member may be integrally merged with the low potential voltage line VSS. A width of the central region of the elongated member may be less than a width of the polygonal member. The polygonal member may have a rectangular or square shape. The polygonal member may have a shape corresponding to a rounded rectangle or a rounded square.

Hereinafter, a detailed structure of the display apparatus 100 according to one or more examples of the present disclosure will be described in detail with reference to the accompanying drawings.

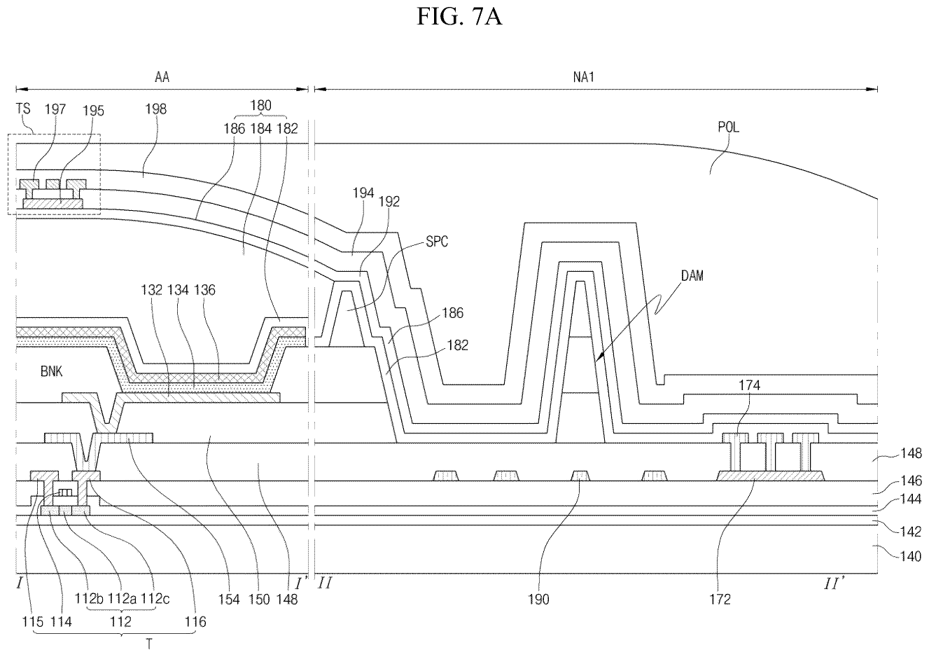

FIGS. 7A and 7B are cross-sectional views illustrating a display apparatus 100 according to a first embodiment of the present disclosure, and are cross-sectional views taken along a line I-I′ and a line II-II′ of FIG. 5. In this case, for convenience of explanation, the cross-sectional views taken along line II-II′ of FIG. 5 are divided into FIGS. 7A and 7B.

As shown in FIGS. 7A and 7B, the substrate 140 includes the display area AA and the non-display area NA. The substrate 140 may be formed of a rigid material such as glass or a plastic-based material having ductility.

When the first substrate 140 is formed of the plastic material, the first substrate 140 may be made of at least one material of a polyimide, a polymethylmethacrylate, a polyethylene tereththalate, a Polyethersulfone, and a Polycarbonate, but not limited thereto.

When the first substrate 140 is made of polyimide, the substrate 140 may be made of a plurality of polyimide layers, and an inorganic layer may be further disposed between the polyimide layers, but is not limited thereto.

The buffer layer 142 may be formed on the substrate 140 to enhance adhering force between the first substrate 140 and the layers thereon. Further, the buffer layer 142 may block various types of defects, such as alkali components flowing out from the substrate 140. In addition, the buffer layer 142 may delay diffusion of moisture or oxygen penetrating into the substrate 140.

The buffer layer 142 may be a single layer made of silicon oxide (SiOx) or silicon nitride (SiNx), or multi-layers thereof. When the buffer layer 142 is made of multiple layers, SiOx and SiNx may be alternately formed. The buffer layer 142 may be omitted based on the type and material of the first substrate 140, the structure and type of the thin film transistor, and the like.

A thin film transistor T is formed in the display area AA on the buffer layer 142. For convenience of description, only the driving thin film transistor among various thin film transistors that may be disposed in the active area AA is illustrated, but other thin film transistors such as switching thin film transistors may also be included. In the figure, the thin film transistor of a top gate structure is shown, but the thin film transistor is not limited to this structure and may be formed in other structures such as the thin film transistor of a bottom gate structure.

The thin film transistor T includes a semiconductor pattern 112 disposed on the buffer layer 142, a gate insulating layer 144 covering the semiconductor pattern 112, a gate electrode 114 on the gate insulating layer 144, an interlayer insulating layer 146 covering the gate electrode 114, and a source electrode 115 and a drain electrode 116 on the interlayer insulating layer 146.

The semiconductor pattern 112 may be made of a polycrystalline semiconductor. For example, the polycrystalline semiconductor may be made of low temperature poly silicon (LTPS) having high mobility, but is not limited thereto.

The semiconductor pattern 112 may be made of an oxide semiconductor. For example, semiconductor pattern 112 may be made of one of IGZO (Indium-gallium-zinc-oxide), IZO (Indium-zinc-oxide), IGTO (Indium-gallium-tin-oxide), and IGO (Indium-gallium-oxide), but is not limited thereto. The semiconductor pattern 112 includes a channel region 112a in a central region and a source region 112b and a drain region 112c which are doped layers at both sides of the channel region 112a.

The gate insulating layer 144 may be formed in the display area AA and the non-display area NA. Further, the gate insulating layer 144 may be formed only in the display area AA. The gate insulating layer 144 may be formed in the display area AA and the non-display area NA. Also, the gate insulating layer 144 may be formed only in the display area AA.

The gate electrode 114 is made of a metal. For example, the gate electrode 114 may be formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto.

The interlayer insulating layer 146 may be formed in the display area AA and the non-display area NA. Further, the gate insulating layer 144 may be formed only in the display area AA. The interlayer insulating layer 146 may be made of the organic material such as photo-acryl, or the interlayer insulating layer 146 may formed of the single layer or the multiple layers made of the inorganic material such as SiOx or SiNx, but is not limited thereto. Further, the interlayer insulating layer 146 may be formed of the multi layers of the organic material layer and the inorganic material layer, but is not limited thereto.

The source electrode 115 and the drain electrode 116 are formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto. The source electrode 115 and the drain electrode 116 may be respectively contacted to the source region 112b and the drain region 112c of the semiconductor through contact holes formed in the gate insulating layer 144 and the interlayer insulating layer 146.

Although not shown in figure, a bottom shield metal layer may be disposed on the substrate 140 under the semiconductor pattern 112. The bottom shield metal layer minimizes a backchannel phenomenon caused by charges trapped in the first substrate 140 to prevent afterimages or deterioration of transistor performance. The bottom shield metal layer may be composed of the single layer or the multi layers made of titanium (Ti), molybdenum (Mo), or an alloy thereof, but is not limited thereto.

A first planarization layer 148 is formed on the substrate where the thin film transistor T is disposed. The first planarization layer 148 may be formed of the organic material such as photo acrylic. But it is not limited thereto. The first planarization layer 148 may include a plurality of layers including the inorganic layer and the organic layer.

A connection pattern 154 is disposed on the first planarization layer 148 to be electrically connected to the drain electrode 116 of the thin film transistor T through the contact hole formed in the first planarization layer 148.

The connection pattern 154 may be formed of metal. As described later, for example, the connection pattern 154 may be formed of three metal layers.

A second planarization layer 150 is formed on the first planarization layer 148 on which the connection pattern 154 is disposed. The second planarization layer 150 may be formed of the organic material such as photo acrylic. But it is not limited thereto. The second planarization layer 150 may include a plurality of layers including the inorganic layer and the organic layer. Further, the second planarization layer 150 may be made of the same material as the first planarization layer 148, but may be made of a different material.

As described above, in one or more aspects of the present disclosure, various electrodes and signal lines may be formed between the first and second planarization layers 148 and 150 by forming the planarization layer in the two-layer structure 148 and 150. Therefore, since the electrodes may be vertically arranged, the area of electrodes and signal lines in the subpixel may be reduced, and as a result, the area of the sub-pixel may be reduced and thus the high-resolution display apparatus 100 may be manufactured.

A light emitting device D is disposed on the second planarization layer 150. The light emitting device D includes a first electrode 132, a light emitting layer 134, and a second electrode 136.

The first electrode 132 is disposed on the second planarization layer 150 and electrically connected to the drain electrode 116 of the thin film transistor T through the contact hole formed in the planarization layer 148. The first electrode 132 may be formed of at least one of silver (Ag), aluminum (Al), gold (Au), molybdenum (Mo), tungsten (W), chromium (Cr), or an alloy thereof. Further, the first electrode 132 may be formed of a transparent metal oxide material such as indium tin oxide (ITO) or indium zinc oxide (IZO).

When the display apparatus 100 is a top emission type display apparatus, the first electrode 132 may further include an opaque conductive material layer to function as a reflective electrode that reflects light. When the display apparatus 100 is a bottom emission type display apparatus, the first electrode 132 may be made of the transparent conductive material such as ITO or IZO.

A bank layer BNK is formed at the boundary between the sub-pixels on the second planarization layer 150. The bank layer BNK may be a barrier wall to define sub-pixels SP1 and SP2. The bank layer BNK divides each sub-pixel to prevent light of a specific color output from adjacent pixels from being mixed and output.

The bank layer BNK is made of at least one material of the inorganic insulating material such as SiNx or SiOx, the organic insulating material such as Benzo Cyclo Butene, acrylic resin, epoxy resin, phenolic resin, polyamide resin, or the photosensitizer including black pigment, but is not limited thereto.

The light emitting layer 13) can be formed on the upper surface of the first electrode 132, the inclined surfaces of the bank layer BNK, and at least a portion of the upper surface of the bank layer BNK. The light emitting layer 134 may be formed in the R, G, and B pixels and may include an R-emitting layer that emits red light, a G-emitting layer that emits green light, and a B-emitting layer that emits blue light. For example, The light emitting layer 134 may include an organic light emitting layer, an inorganic light emitting layer, a nano-sized material layer, a quantum dot, a micro LED light emitting layer, or a mini LED light emitting layer, but is not limited thereto.

The light emitting layer 134 may further include an electron injecting layer for injecting electrons into the light emitting layer, a hole injecting layer for injecting holes into the light emitting layer, an electron transporting layer for transporting the injected electrons to the light emitting layer, a hole transporting layer for transporting the injected holes to the light emitting layer, an electron blocking layer, and a hole blocking layer, but is not limited thereto.

The second electrode 136 is disposed on the light emitting layer 134 and may be formed of the single layer or the multi layers made of metal or alloy thereof. Further, the second electrode 136 may be formed of a transparent metal oxide such as indium tin oxide (ITO) or indium zinc oxide (IZO), but is not limited thereto.

When the display apparatus 100 is the top emission type, the second electrode 136 may be made of the half-transparent conductive material that transmits light. For example, the second electrode 136 may be made of at least one or more of the alloys such as LiF/Al, CsF/Al, Mg:Ag, Ca/Ag, Ca:Ag, LiF/Mg:Ag, LiF/Ca/Ag, or LiF/Ca:Ag.

When the display apparatus 100 is the bottom emission type, the second electrode 136 may be the reflective electrode made of the opaque conductive material. For example, the second electrode 136 may be made of at least one or more of silver (Ag), aluminum (Al), gold (Au), molybdenum (Mo), tungsten (W), chromium (Cr), or alloys thereof.

Further, the light emitting device D may be formed in a tandem structure. The tandem structure may include a plurality of organic light emitting layers and a charge generating layer disposed between the organic light emitting layers. The charge generating layer is disposed to adjust the charge balance between the plurality of organic light emitting layers, and may be formed of a plurality of layers including a first charge generating layer and a second charge generating layer. The charge generating layer may include an N-type charge generating layer and a P-type charge generating layer. In this case, the charge generating layer may be formed of the organic layer doped with an alkali metal such as Li, Na, K, or Cs or an alkaline earth metal such as Mg, Sr, Ba, or Ra, but is not limited thereto.

An encapsulation layer 180 is formed in the display area AA and the non-display area NA to encapsulate the light emitting device D. When the light emitting device D is exposed to impurities such as moisture or oxygen, a pixel shrinkage phenomenon in which the light emitting area is reduced or the defect such as a dark spot in the light emitting area may occur. Further, moisture or oxygen penetrating the light emitting device D oxidizes the metal electrode. The encapsulation layer 180 blocks impurities such as oxygen and moisture from the outside to prevent defects of the light emitting device D and various electrodes.

The encapsulation layer 180 may include a first encapsulation layer 182, a second encapsulation layer 184, and a third encapsulation layer 186, but is not limited thereto. The encapsulation layer 180 may be formed of two layers or four or more layers.

The first encapsulation layer 182 and the third encapsulation layer 186 may be formed of the inorganic material such as SiOx, SiON, SiNx, or the like, and may further include the organic material between inorganic materials such as SiOx, SiON, or SiNx, but are not limited thereto. The second encapsulation layer 184 may be formed of the organic insulating material such as epoxy resin.

A touch buffer layer 192 is formed on the encapsulation layer 180, and a touch sensor TS is disposed thereon. The touch sensor TS includes a bridge electrode 195 disposed on the touch buffer layer 192, a touch interlayer insulating layer 194 disposed on the bridge electrode 195, and a touch electrode 197 disposed on the touch interlayer insulating layer 194.

The touch buffer layer 192 and the touch interlayer insulating layer 194 may be made of the inorganic material. For example, the touch buffer layer 192 and the touch interlayer insulating layer 194 may be made of silicon oxide (SiOx) or silicon nitride (SiNx), but are not limited thereto.

The bridge electrode 195 and the touch electrode 197 may be formed of the single layer or the multiple layers made of one or an alloy of molybdenum (Mo), aluminum (Al), chromium (Cr), gold (Au), titanium (Ti), nickel (Ni), neodymium (Nd), and copper (Cu). Further, the bridge electrode 195 and the touch electrode 197 may be made of the transparent metal oxide such as ITO or IZO.

The bridge electrode 195 and the touch electrode 197 are electrically connected to each other through the contact hole formed in the touch interlayer insulating layer 194. Although not shown in the drawing, the touch electrode 197 may be formed in a mesh shape.

A touch planarization layer 198 is formed on the touch sensor TS to protect the touch sensor TS. The touch planarization layer 198 may be made of the organic material, or may be formed of a plurality of layers of the organic layer and the inorganic layer.

A polarization member POL is formed in the display area AA and the first non-display area NA1. The polarization member POL is formed on the light output side of the display apparatus 100, that is, on the screen side on which the image is displayed, to prevent reflection of light incident from the outside.

The polarizing member POL may be formed of a polyvinyl alcohol-based polarizing layer in which at least one of iodine and dichroic dyes is oriented in a predetermined direction. For example, the polarization member POL may be the polyvinyl alcohol-based polarization layer in which iodine and/or dichroic dyes are oriented in a certain direction, or a film laminate including the polyvinyl alcohol-based polarizing layer and a transparent polymer film attached to one side thereof.

Meanwhile, the polarizing member POL may be omitted according to the structure of the display apparatus 100.

A plurality of moisture blocking patterns 190 are disposed on the interlayer insulating layer 146 of the first non-display area NA1. The moisture blocking pattern 190 is integrally formed with the low potential voltage line VSS. In this case, the moisture blocking pattern 190 is formed by patterning the edge region of the low potential voltage line VSS.

As will be described below in detail, the low potential voltage line VSS and the moisture blocking pattern 190 may be formed of multiple metal patterns.

The first planarization layer 148, the second planarization layer 150, and the bank layer BNK may be formed only in a partial area of the first non-display area NA1, for example, in the area adjacent to the display area AA, and may be removed in another area of the first non-display area NA1. The moisture blocking pattern 190 may be disposed in the area from which the first planarization layer 148, the second planarization layer 150, and the bank layer BNK of the first non-display area NA1 are removed.

A spacer SPC is disposed on the bank layer BNK of the first non-display area NA1. The spacer SPC is for supporting a metal mask when forming the light emitting layer 134 of the light emitting device D. The spacer SPC may be formed of the single layer made of the organic material, or may be formed of the multi layers made of the inorganic material and the organic material. The spacer SPC may be formed to surround the display area AA. Although only one spacer SPC is disposed in the drawing, a plurality of spacers SPC may be disposed to be spaced apart from each other by a predetermined distance.

A dam DAM is disposed on the interlayer insulating layer 146 of the first non-display area NA1. Since the organic material forming the second encapsulation layer 184 has fluidity, when the second encapsulation layer 184 is formed, the organic material may flow out of the substrate 140 after passing to the outside of the non-display area NA due to fluidity. The dam DAM is formed to surround the display area AA and traps the organic material flowing out of the substrate 140 when the second encapsulation layer 184 is formed, thereby blocking the organic material flowing out of the substrate 140. Although only one dam DAM is disposed in the drawing, a plurality of dams DAM may be disposed.

The dam DAM may be formed of a plurality of layers. For example, the dam DAM may be formed of the layer of the same material as those of the first planarization layer 148, the second planarization layer 150, and the bank layer BNK. However, the dam DAM of the present disclosure is not limited thereto, but may be formed of two layers or a single layer.

The dam DAM may be disposed above the moisture blocking pattern 190 to be overlapped with the moisture blocking pattern 190. In this case, the dam DAM may be overlapped one moisture blocking pattern 190 or may be overlapped a plurality of dams DAM. The positional relationship between the dam DAM and the moisture blocking pattern 190 may be variously set according to the design of the display apparatus 100.

The first encapsulation layer 182 and the third encapsulation layer 186 may be formed in the display area AA and some areas of the first non-display area NA1. Further, the second encapsulation layer 184 may be formed only to the spacer SPC of the first non-display area NA1 in the display area AA or may be formed only to the dam DAM of the first non-display area NA1 in the display area AA.

In the first non-display area NA1, since only the first encapsulation layer 182 and the third encapsulation layer 186 made of the inorganic material are formed and the second encapsulation layer 184 made of the organic material is not formed, the moisture penetration through the end of the non-display area NA may be minimized.

Also, a plurality of signal lines 172 and 174 may be disposed in the non-display area NA. In the drawing, the signal lines 172 and 174 are formed only on the interlayer insulating layer 146 and the first planarization layer 148, but signal lines 172 and 174 may also be formed on the gate insulating layer 144 and the buffer layer 142. For example, the signal lines 172 and 174 include the low potential voltage link line and the high potential voltage link line, but are not limited thereto.

The buffer layer 142, the first planarization layer 148, the second planarization layer 150, the bank layer BNK, the touch planarization layer 198, and the micro-coating layer MCL are formed in the bending area BA. Therefore, since the gate insulating layer 144, the interlayer insulating layer 146, the encapsulation layer 180, the touch buffer layer 192, the touch intermediate insulating layer 194, and the touch planarization layer 198 are not formed in the bending area BA, the application of stress may be minimized.

The link line 178 is formed on the first planarization layer 148 of the bending area BA to be electrically connected to the third signal line 177 of the second non-display area NA2 through the contact hole formed in the first planarization layer 148.

Further, the link line 178 is electrically connected to the first signal line 172 formed in the interlayer insulating layer 146 of the first non-display area NA1 through the contact hole formed in the first planarization layer 148. Accordingly, various signals supplied from the outside through the third signal line 177, for example, the low potential voltage or the high potential voltage, are applied to the first signal lines 172 and the second signal line 174 through the link line 178.

The micro-coating layer MCL is disposed on the link line 178 to position the neutral surface of the display apparatus 100 over the link line 178 to prevent stress applied to the link line 178 when bending the bending area BA.

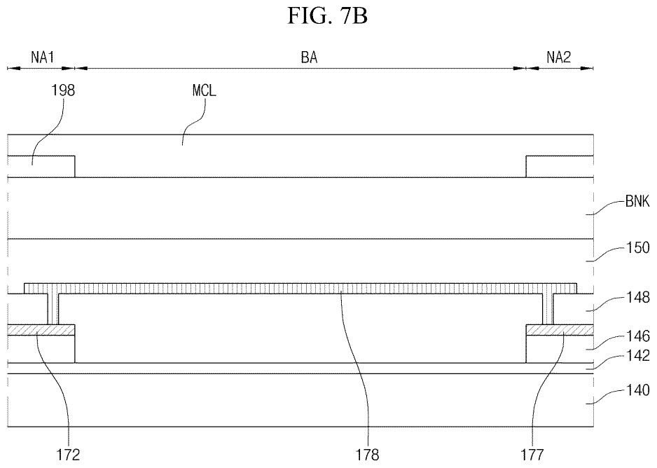

FIGS. 8A and 8B are the enlarged cross-sectional views of the connection pattern 154 and the moisture blocking pattern 190, respectively.

As shown in FIG. 8A, the connection pattern 154 may include first to third connection pattern layers 154a, 154b, and 154c. For example, the first connection pattern layer 154a may be made of titanium (Ti), the second connection pattern layer 154b may be made of aluminum (Al), and the third connection pattern layer 154c may be made of titanium (Ti).

When the connection pattern 154 is formed by patterning the metal having high conductivity, such as Al, Al having high oxidation properties may be oxidized by combining with oxygen. On the other hand, since Ti has lower oxidation properties than Al, it is unlikely to be oxidized by combining with oxygen during patterning of the metal. Therefore, when Ti having low oxidation properties, Al having high oxidation properties and high conductivity, and Ti having low oxidation properties are continuously deposited to form a Ti/Al/Ti layer, and then the Ti/Al/Ti layer is patterned, so that Al located in the middle of the Ti/Al/Ti layer does not combine with oxygen, thereby preventing the oxidation of Al.

The etching rate of Ti is less than the etching rate of Al. Therefore, when the Ti/Al/Ti layer is patterned, Al is over-etched as compared with Ti, and thus the first connection pattern layer 154a and the third connection pattern layer 154c extend from the end of the second connection pattern layer 154b in both side directions. That is, the second connection pattern layer 154b and the third connection pattern layer 154c are formed in an overhang structure having an inverse step difference.

As shown in FIG. 8B, the moisture blocking pattern 190 includes first to fourth moisture blocking pattern layers 190a, 190b, 190c, and 190d. The first and third moisture blocking pattern layers 190a and 190c may be made of the metal having low oxidation properties, such as Ti. The second blocking prevention pattern layer 190b may be made of the metal having good conductivity, such as Al.

Like the connection pattern 154, the first moisture blocking pattern layer 190a and the third moisture blocking pattern layer 190c are extended on both sides from the end of the second moisture blocking pattern layer 190b. That is, the second moisture blocking pattern layer 190b and the third moisture blocking pattern layer 190c are formed in the overhang structure having the inverse step.

The first and third moisture blocking pattern layers 190a and 190c may be made of the same metal by the same process as the first to third connection pattern layers 154a, 154b and 154c of the connection pattern 154, but may be formed of a different metal by a different process from the first to third connection pattern layers 154a, 154b and 154c.

The fourth moisture blocking pattern layer 190d is formed to surround surfaces of the first to third moisture blocking pattern layers 190a, 190b, and 190c. The fourth moisture blocking pattern layer 190d may be formed of the same material by the same process as that of the first electrode 132 of the light emitting device D. For example, the fourth moisture blocking pattern layer 190d may be made of at least one of silver (Ag), aluminum (Al), gold (Au), molybdenum (Mo), tungsten (W), chromium (Cr), or an alloy thereof, and may be formed of a transparent metal oxide layer such as indium tin oxide (ITO), indium zinc oxide (IZO), etc.

In one or more aspects of the present disclosure, since the fourth moisture blocking pattern layer 190d is formed to surround the surfaces of the first to third blocking pattern layers 190a, 190b, and 190c, the defects caused by the overhang structure of the second moisture blocking pattern layer 190b and the third moisture blocking pattern layer 190c may be prevented. Hereinafter, this will be described in detail.

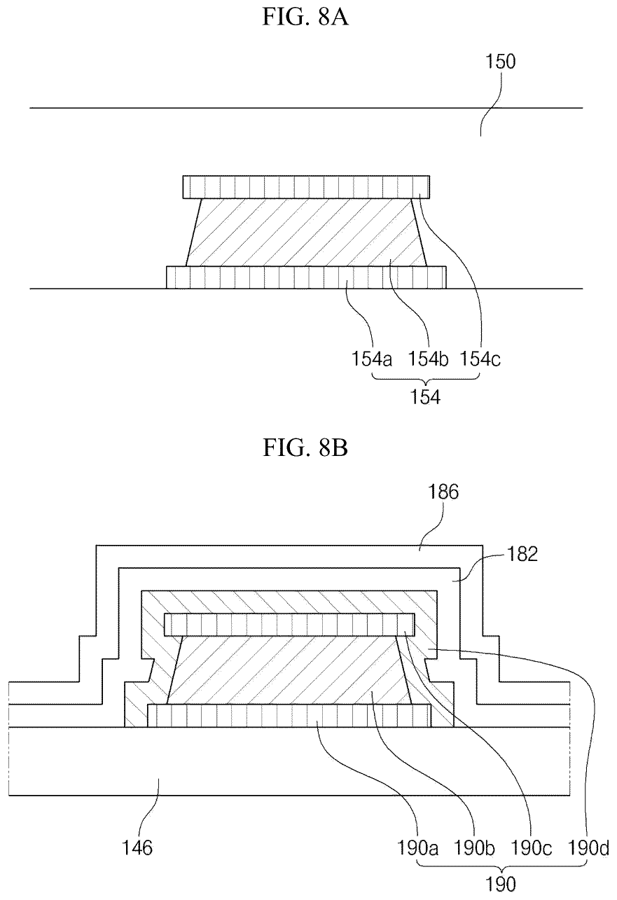

FIG. 9 is the view showing a case where the moisture blocking pattern 290 includes only the first to third moisture blocking pattern layers 290a, 290b, and 290c and the fourth moisture blocking pattern layer 290d surrounding the first to third moisture blocking pattern layers 290a, 290b, and 290c is not provided.

As shown in FIG. 9, the moisture blocking pattern 290 is disposed on the interlayer insulating layer 246, and encapsulation layers 282 and 286 are formed thereon. In this case, the second encapsulation layer made of the organic material is formed only in the display area AA and inside the non-display area NA except the moisture blocking pattern 290. That is, the first encapsulation layer 282 and the third encapsulation layer 286 made of the inorganic material are directly formed on the moisture blocking pattern 290.

At this time, since the second and third moisture blocking pattern layers 290b and 290c are formed in an overhang structure having an inverse step, a seam region having a thickness thinner than that of other regions is generated in the first encapsulation layer 282 and the third encapsulation layer 286 in the reverse step region. In the seam region, the cracks can be generated when then external impact is applied due to the thin thickness.

In particular, as shown in FIG. 5, since the stress is continuously applied to the moisture blocking pattern 290 adjacent to the bending area BA by bending of the display apparatus 100, the cracks are generated in the thin seam region due to the stress. Since the cracks cause moisture penetration from the outside, the original task of the moisture blocking pattern 290 cannot be performed due to cracks in the seam region.

In one or more aspects of the present disclosure, since the fourth moisture blocking pattern layer 190d is formed to surround the first to third moisture blocking pattern layers 190a, 190b, and 190c, the fourth moisture blocking pattern layer 190d is disposed in the overhang regions of the second and third moisture blocking pattern layers 190b and 190c. Therefore, since the degree of reverse step difference between the second and third moisture blocking pattern layers 190b and 190c is alleviated by the fourth moisture blocking pattern layer 190d, the seam region of the first encapsulation layer 182 and the third encapsulation layer 186 is not generated in the overhang region.

As a result, the cracks are not generated in the first encapsulation layer 182 and the third encapsulation layer 186 where the impact or the stress is applied from the outside or periodically, so the moisture into the display apparatus 100 through cracks can be prevented.

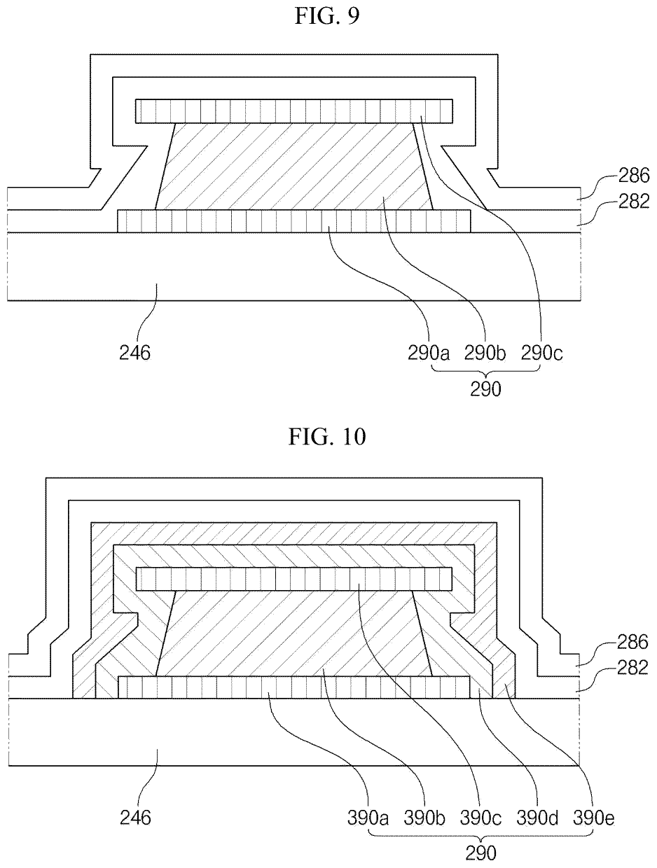

FIG. 10 is an enlarged cross-sectional view of the moisture blocking pattern 390 of the display apparatus according to a second embodiment of the present disclosure.

As shown in FIG. 10, in the display apparatus accordance to the second embodiment of the present disclosure, the moisture blocking pattern 290 includes first to fifth moisture blocking pattern layers 390a, 390b, 390c, 390d, and 390e.

The first and third moisture blocking pattern layers 390a and 390c may be made of the metal having low oxidizing properties, such as Ti. The second moisture blocking pattern layer 390b may be made of the metal having good conductivity, such as Al. In this case, the second moisture blocking pattern layer 390b and the third moisture blocking pattern layer 390c are formed in the overhang structure having an inverse step.

The fourth moisture blocking pattern layer 390d is formed to surround surfaces of the first to third moisture blocking pattern layers 390a, 390b, and 390c. The fourth moisture blocking pattern layer 390d may be formed of the same material by the same process as the first electrode of the light emitting device D. For example, the fourth moisture blocking pattern layer 390d may be made of silver (Ag), aluminum (Al), gold (Au), molybdenum (Mo), tungsten (W), chromium (Cr), or an alloy thereof, and may be formed of the transparent metal oxide layer such as indium tin oxide (ITO), indium zinc oxide (IZO), etc.

The fifth moisture blocking pattern layer 390e is formed to surround the fourth moisture blocking pattern layer 390d. The fifth moisture blocking pattern layer 390e may be formed of the same material by the same process as the second electrode of the light emitting device D. For example, the fifth moisture blocking pattern layer 390e may be made of at least one of alloys such as LiF/Al, CsF/Al, Mg:Ag, Ca/Ag, LiF/Mg:Ag, LiF/Ca/Ag, LiF/Ca:Ag. Further, the fifth moisture blocking pattern layer 390e may be made of at least one of silver (Ag), aluminum (Al), gold (Au), molybdenum (Mo), tungsten (W), chromium (Cr), or an alloy thereof.

In this embodiment, since the fourth moisture blocking pattern layer 390d is formed to surround the surfaces of the first to third moisture blocking pattern layers 390a, 390b, and 390c, and the fifth moisture blocking pattern layer 390e is formed to surround the fourth moisture blocking pattern layer 390d, the inverse step difference between the second moisture blocking pattern layer 390b and the third moisture blocking pattern layer 390c can be further alleviated, and as a result, the defects due to the overhang structure can be prevented more efficiently.

Various examples and aspects of the present disclosure are described below. These are provided as examples, and do not limit the scope of the present disclosure.

According to one or more example embodiments of the present disclosure, the display apparatus comprises the substrate, the display area having a plurality of sub-pixels, the non-display area outside the display area, the transistor and the light emitting device disposed in each of the plurality of sub-pixels, the voltage line disposed in the non-display area to supply the voltage from outside to the display area, and the moisture blocking pattern disposed at at least one side of the voltage line, wherein the moisture blocking pattern includes the first moisture blocking pattern layer, the second moisture blocking pattern layer, the third moisture blocking pattern layer having a smaller width than the first moisture blocking pattern layer and the second moisture blocking pattern layer, and the fourth moisture blocking pattern layer surrounding the first, second, and third moisture blocking pattern layers.

According to one or more example embodiments of the present disclosure, the light emitting device may include the first electrode, the light emitting layer on the first electrode, and the second electrode on the light emitting layer.

According to one or more example embodiments of the present disclosure, the fourth moisture blocking pattern layer may be made of the same material as the first electrode of the light emitting device.

According to one or more example embodiments of the present disclosure, the moisture blocking pattern further may include the fifth moisture blocking pattern layer surrounding the fourth moisture blocking pattern layer.

According to one or more example embodiments of the present disclosure, the fifth moisture blocking pattern layer may be made of the same material as the second electrode of the light emitting device.

According to one or more example embodiments of the present disclosure, the non-display area may include the bending area.

According to one or more example embodiments of the present disclosure, the moisture blocking pattern may be disposed between the bending area and the display area.

According to one or more example embodiments of the present disclosure, the voltage line may include the low potential voltage line.

According to one or more example embodiments of the present disclosure, the moisture blocking pattern may be integrally formed with the low potential voltage line.

According to one or more example embodiments of the present disclosure, the moisture blocking pattern may include a plurality of hammer shaped patterns.

According to one or more example embodiments of the present disclosure, the encapsulation layer may be disposed over the display area and the non-display area, and the encapsulation layer may include a first encapsulation layer made of an inorganic material, a second encapsulation layer made of an organic material on the first encapsulation layer, and a third encapsulation layer made of the inorganic material on the second encapsulation layer.

According to one or more example embodiments of the present disclosure, the first and third encapsulation layers may be extended to the non-display area to cover the moisture blocking pattern.

According to one or more example embodiments of the present disclosure, the dam may surround the display area, and the dam may be overlapped with the moisture blocking pattern.

According to one or more example embodiments of the present disclosure, a display apparatus comprises a display area for displaying an image, a non-display area outside the display area, a voltage line to supply a voltage to the display area, and a moisture blocking pattern disposed at at least one side of the voltage line, wherein the moisture blocking pattern includes one or more moisture blocking pattern layers and another moisture blocking pattern layer surrounding the one or more moisture blocking pattern layers.

According to one or more example embodiments of the present disclosure, in a cross-sectional view, the another moisture blocking pattern layer may enclose an entirety of a top surface and side surfaces of the one or more moisture blocking pattern layers.

According to one or more example embodiments of the present disclosure, the one or more moisture blocking pattern layers may provide an inverse step that protrudes inwardly by a first distance along a horizontal direction, the another moisture blocking pattern layer may provide a second inverse step that protrudes inwardly by a second distance along the horizontal direction, and the second distance may be less than the first distance.

According to one or more example embodiments of the present disclosure, the non-display area may include a bending area, and the moisture blocking pattern may be disposed adjacent to the bending area.

According to one or more example embodiments of the present disclosure, the moisture blocking pattern may include a plurality of structures arranged in a row or a column in a plan view, along the voltage line, and each of the plurality of structures may include an elongated member and a polygonal member.

According to one or more example embodiments of the present disclosure, the elongated member may have a central region of uniform width and oppositely disposed end regions of increased width, one end of the elongated member may be integrally merged with the polygonal member, and a width of the central region may be less than a width of the polygonal member.

According to one or more example embodiments of the present disclosure, the moisture blocking pattern may comprise an electrically conductive material.

The description herein has been presented to enable any person skilled in the art to make, use and practice the technical features of the present disclosure, and has been provided in the context of one or more particular example applications and their example requirements. Various modifications, additions and substitutions to the described embodiments will be readily apparent to those skilled in the art, and the principles described herein may be applied to other embodiments and applications without departing from the scope of the present disclosure. The description herein and the accompanying drawings provide non-limiting examples of the technical features of the present disclosure for illustrative purposes. In other words, the disclosed embodiments illustrate the scope of the technical features of the present disclosure and are not intended to be limiting in any respect. Thus, the scope of the present disclosure is not limited to the embodiments shown, but is to be accorded the widest scope consistent with the claims and their equivalents.

What is claimed is:

1. A display apparatus, comprising:
a substrate;
a display area having a plurality of sub-pixels and a non-display area outside the display area;
a transistor and a light emitting device disposed in each of the plurality of sub-pixels;
a voltage line disposed in the non-display area to supply a voltage from outside to the display area; and
a moisture blocking pattern disposed at at least one side of the voltage line,
wherein the moisture blocking pattern includes a first moisture blocking pattern layer, a second moisture blocking pattern layer, a third moisture blocking pattern layer having a smaller width than the first moisture blocking pattern layer and the second moisture blocking pattern layer, and a fourth moisture blocking pattern layer surrounding the first, second, and third moisture blocking pattern layers.

2. The display apparatus of claim 1, wherein the light emitting device includes:
a first electrode;
a light emitting layer on the first electrode; and
a second electrode on the light emitting layer.

3. The display apparatus of claim 2, wherein the fourth moisture blocking pattern layer is made of a same material as the first electrode of the light emitting device.

4. The display apparatus of claim 3, wherein the moisture blocking pattern further includes a fifth moisture blocking pattern layer surrounding the fourth moisture blocking pattern layer.

5. The display apparatus of claim 4, wherein the fifth moisture blocking pattern layer is made of a same material as the second electrode of the light emitting device.

6. The display apparatus of claim 1, wherein the non-display area includes a bending area.

7. The display apparatus of claim 6, wherein the moisture blocking pattern is disposed between the bending area and the display area.

8. The display apparatus of claim 1, wherein the voltage line includes a low potential voltage line.

9. The display apparatus of claim 8, wherein the moisture blocking pattern is integrally formed with the low potential voltage line.

10. The display apparatus of claim 9, wherein the moisture blocking pattern includes a plurality of hammer shaped patterns.

11. The display apparatus of claim 1, further comprising an encapsulation layer disposed over the display area and the non-display area,
wherein the encapsulation layer includes a first encapsulation layer made of an inorganic material, a second encapsulation layer made of an organic material on the first encapsulation layer, and a third encapsulation layer made of the inorganic material on the second encapsulation layer.

12. The display apparatus of claim 11, wherein the first and third encapsulation layers are extended to the non-display area to cover the moisture blocking pattern.

13. The display apparatus of claim 1, further comprising a dam surrounding the display area,
wherein the dam is overlapped with the moisture blocking pattern.

14. A display apparatus, comprising:
a display area for displaying an image and a non-display area outside the display area;
a voltage line to supply a voltage to the display area; and
a moisture blocking pattern disposed at at least one side of the voltage line,
wherein the moisture blocking pattern includes one or more moisture blocking pattern layers and another moisture blocking pattern layer surrounding the one or more moisture blocking pattern layers.

15. The display apparatus of claim 14, wherein in a cross-sectional view, the another moisture blocking pattern layer encloses an entirety of a top surface and side surfaces of the one or more moisture blocking pattern layers.

16. The display apparatus of claim 14, wherein the one or more moisture blocking pattern layers provide an inverse step that protrudes inwardly by a first distance along a horizontal direction,
wherein the another moisture blocking pattern layer provides a second inverse step that protrudes inwardly by a second distance along the horizontal direction, and
wherein the second distance is less than the first distance.

17. The display apparatus of claim 14, wherein the non-display area includes a bending area, and
wherein the moisture blocking pattern is disposed adjacent to the bending area.

18. The display apparatus of claim 14, wherein the moisture blocking pattern includes a plurality of structures arranged in a row or a column in a plan view, along the voltage line, and
wherein each of the plurality of structures includes an elongated member and a polygonal member.

19. The display apparatus of claim 18, wherein the elongated member has a central region of uniform width and oppositely disposed end regions of increased width,
wherein one end of the elongated member is integrally merged with the polygonal member, and
wherein a width of the central region is less than a width of the polygonal member.

20. The display apparatus of claim 18, wherein the moisture blocking pattern comprises an electrically conductive material.
